(19) United States
(12) Patent Application Publication
(10) Pub. No.: US 2006/0121314 A1
(43) Pub. Date: Jun. 8, 2006

(54) Electroluminescent polymer having 9-fluoren-2-yl-9-aryl-2,7-fluorenyl unit and electroluminescent device manufactured using the same

(75) Inventors: Weon Jung Choi, Daejeon (KR); Dong Cheol Shin, Daejeon (KR); Soon Ki Kwon, Gyeongsangnam-do (KR); Yun Hi Kim, Gyeongsangnam-do (KR)

Correspondence Address: DARBY & DARBY P.C., P. O. BOX 5257, NEW YORK, NY, 10150-5257, US

(73) Assignee: SK CORPORATION, Seoul (KR)

(21) Appl. No.: 11/296,059

(22) Filed: Dec. 6, 2005

(30) Foreign Application Priority Data
Dec. 6, 2004 (KR) 10-2004-0101895
Oct. 25, 2005 (KR) 10-2005-0100865

(51) Int. Cl. C09K 11/06; C08G 61/00; H01L 51/54; H05B 33/14

(52) U.S. Cl. 428/690; 428/917; 526/280; 528/422; 528/211; 528/86; 528/397; 313/504; 313/506; 257/40; 257/E51.032

(57) ABSTRACT

Disclosed herein is an electroluminescent polymer having a 9-fluoren-2-yl-9-aryl-2,7-fluorenyl unit and an electroluminescent device using the same. Specifically, an electroluminescent polymer having a 9-fluoren-2-yl-9-aryl-2,7-fluorenyl unit, which can be used as a blue electroluminescent polymer and a host material by introducing the substituted fluorenyl group at the 9-position of fluorene, and an electroluminescent device using the electroluminescent polymer. The electroluminescent polymer is applicable as a host material for highly pure blue, green and red luminescence, and has high solubility, high heat stability and high quantum efficiency.

### INCORPORATION BY REFERENCE

The present application claims priority under 35 U.S.C. §119 to Korean Patent Application Nos. 10-2004-0101895 filed on Dec. 6, 2004 and 10-2005-0100865 filed on Oct. 25, 2005. The content of the applications is incorporated herein by reference in its entirety.

### BACKGROUND OF THE INVENTION

1. Field of the Invention

The present invention relates to an electroluminescent polymer having a 9-fluoren-2-yl-9-aryl-2,7-fluorenyl unit and an electroluminescent device manufactured using the same. More specifically, the present invention relates to an electroluminescent polymer having a 9-fluoren-2-yl-9-aryl-2,7-fluorenyl unit, which exhibits excellent heat stability, light stability, solubility and film formability and high quantum efficiency, and an electroluminescent device manufactured using the electroluminescent polymer.

2. Description of the Related Art

With recent great improvement in optical communication and multimedia fields, development toward a highly information-intensive society has accelerated. Accordingly, an optoelectronic device converting a photon into an electron or vice versa has been emphasized in modern information electronic industries.

The semiconductor optoelectronic device is classified into an electroluminescent device, a light receiving device, and combinations thereof.

Most displays fabricated to date are of the light-receiving type, whereas an electroluminescent display has a self-luminous characteristic and thus can exhibit a fast response and high luminance without the need for a backlight. Thus, the electroluminescent display is receiving attention as a next-generation display.

The electroluminescent device is divided into inorganic electroluminescent devices and organic electroluminescent devices, depending on the kind of material for a light emitting layer.

Organic electroluminescence (EL) is a phenomenon where energy is emitted as light when an electron and a hole transferred from a cathode and an anode, respectively, are combined in an organic material by an electric field applied to the organic material. Such electroluminescence of the organic material was reported by Pope et al., 1963. Since a multilayered luminescent device having quantum efficiency of 1% and luminance of 1000 cd/m at 10 V or less has been fabricated with the use of a colorant having the π-conjugated structure of alumina-quinone, by Tang et al. of Eastmann Kodak, 1987, much research has been conducted. This device is advantageous because various materials can be easily synthesized according to a simple synthesis path, and color tuning is easy. However, processability and heat stability are low, and also, upon the application of voltage, Joule heat generated from the light emitting layer causes rearrangement of molecules, thus the device is broken, negatively affecting the luminescence efficiency and service life of the device. Therefore, the use of an organic electroluminescent device having a polymer structure, capable of alleviating the above problems, is increasingly proposed.

In this regard, FIG. 1 shows the structure of a conventional electroluminescent device, comprising substrate/anode/hole transport layer/light emitting layer/electron transport layer/cathode.

As shown in FIG. 1, an anode 12 is formed on a substrate 11. On the anode 12, a hole transport layer 13, a light emitting layer 14, an electron transport layer 15 and a cathode 16 are sequentially formed. As such, the hole transport layer 13, the light emitting layer 14 and the electron transport layer 15 are organic thin films made of an organic compound. The organic electroluminescent device having the above structure is operated as follows.

That is, when voltage is applied to the anode 12 and the cathode 16, the hole injected from the anode 12 is moved to the light emitting layer 14 through the hole transport layer 13. Meanwhile, the electron is injected into the light emitting layer 14 from the cathode 16 through the electron transport layer 15, and the carriers are recombined in the region of the light emitting layer 14, to produce excitons. The excitons are changed from an excited state to a ground state, whereby a fluorescent molecule in the light emitting layer emits light, to form an image.

Organic materials used for the formation of organic films of EL devices may be of low molecular weights or high molecular weights.

Where low molecular weight organic materials are applied, they can be easily purified to an impurity-free state, and thus have excellent luminescence properties. However, low molecular weight materials do not allow inkjet printing or spin coating, and have poor heat resistance such that they are deteriorated or re-crystallized by heat generated during the operation of the device.

On the other hand, in the case of using high molecular weight materials (i.e., polymer) upon the formation of an organic film, an energy level is divided into a conduction band and a valance band, as wave functions of π-electrons present in its backbone overlap each other. The bandgap between the conduction band and the valence band defines the semiconductor properties of the polymer and thus, control of the band gap may allow the visualization of full colors. Such a polymer is called a π-conjugated polymer.

The first development of an EL device based on the conjugated polymer poly(p-phenylenevinylene) (hereinafter referred to as PPV) by a research team, led by Professor R. H. Friend, Cambridge University, England, 1990, stimulated extensive active research into organic polymers having semiconductor properties. In addition to being superior to low molecular weight materials in heat resistance, polymeric materials can be applied to large-surface displays by virtue of their ability to be inkjet printed or spin coated. PPV and polythiophene (Pth) derivatives in which various functional moieties are introduced are reported to be improved in processability and exhibit various colors. However, such PPV and Pth derivatives, although applicable for the emission of red and green light at high efficiency, have difficulty in emitting blue light at high efficiency.

Polyphenylene derivatives and polyfluorene derivatives are reported as blue light-emitting materials. Polyphenylene is of high stability against oxidation and heat, but of poor luminescence efficiency and solubility.

As with the polyfluorene derivatives, the relevant prior arts are as follows:

U.S. Pat. No. 6,255,449 discloses 9-substituted-2,7-dihalofluorene compounds, and oligomers and polymers thereof, which are suitable as luminescent materials, e.g., light emitting or carrier transport layers in light emitting diodes.

U.S. Pat. Nos. 6,309,763 and 6,605,373 disclose an elecroluminescent copolymer containing a fluorine group and an amine group in the repeating unit. According to the '763 patent, such a copolymer is useful as a light emitting layer or a hole transport layer in the electroluminescent device.

WO 02/77060 discloses a conjugated polymer containing spirobifluorene units. According to this reference, the polymer as disclosed therein shows an improved profile property as electroluminescent material in electronic components such as PLED.

As mentioned above, although research into using polyfluorene derivatives as the blue luminescent polymer is being thoroughly carried out, the minimization of interactions among excitons produced between neighboring molecules and the improvement of efficiency and service life still remain as tasks to be realized.

### SUMMARY OF THE INVENTION

Leading to the present invention, intensive and thorough research on electroluminescent polymers, carried out by the present inventors aiming to avoid the problems encountered in the prior arts, resulted in the finding that a fluorene unit disubstituted with a substituted fluorenyl group at a 9-position thereof is contained in an electroluminescent polymer, whereby the electroluminescent polymer can be used as a novel host material for blue, green and red luminescence, having excellent heat stability, high luminescence efficiency and high solubility while minimizing the interaction of molecules and overcoming the disadvantages of conventional polyfluorenes (PFs), and an electroluminescent device using the same can be manufactured.

Accordingly, an object of the present invention is to provide an electroluminescent polymer as a host material required to realize blue, green and red luminescence at high efficiencies, which exhibits high heat and oxidation stability, low interaction of molecules, easy energy transfer, and high luminescence efficiency due to the suppression of a vibronic mode.

Another object of the present invention is to provide an electroluminescent device manufactured using the electroluminescent polymer.

In order to achieve the above objects, the present invention provides an electroluminescent polymer represented by the following Formula 1:

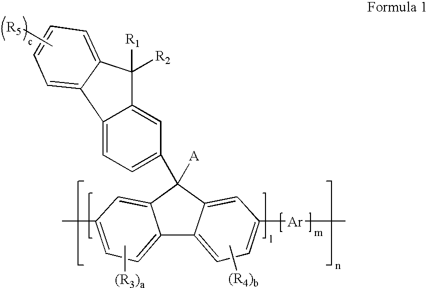

wherein R₁ and R₂ are the same or different, each being a linear or branched alkyl group of 1-20 carbons; an aryl group which is unsubstituted or substituted with at least one substituent group selected from the group consisting of linear or branched alkyl and alkoxy groups of 1-20 carbons; a linear or branched alkyl group of 1-20 carbons having at least one hetero-atom selected from the group consisting of F, S, N, O, P and Si; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si; a substituted or unsubstituted trialkylsilyl group of 3-40 carbons; a substituted or unsubstituted arylsilyl group of 3-40 carbons; a substituted or unsubstituted carbazole group of 12-60 carbons; a substituted or unsubstituted phenothiazine group of 6-60 carbons; or a substituted or unsubstituted arylamine group of 6-60 carbons;

R₃, R₄ and R₅ are the same or different, each being hydrogen; a linear or branched alkyl or alkoxy group of 1-20 carbons; an aryl group which is unsubstituted or substituted with at least one substituent group selected from the group consisting of linear or branched alkyl and alkoxy groups of 1-20 carbons; a linear or branched alkyl or alkoxy group of 1-20 carbons having at least one hetero-atom selected from the group consisting of F, S, N, O, P and Si; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si; a substituted or unsubstituted trialkylsilyl group of 3-40 carbons; a substituted or unsubstituted arylsilyl group of 3-40 carbons; a substituted or unsubstituted carbazole group of 12-60 carbons; a substituted or unsubstituted phenothiazine group of 6-60 carbons; or a substituted or unsubstituted arylamine group of 6-60 carbons;

Integers a, b and c are the same or different, each being an integer from 1 to 3.

A is an aryl group which is unsubstituted or substituted with at least one substituent group selected from the group consisting of linear or branched alkyl and alkoxy groups of 1-20 carbons; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; or an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si;

Ar is selected from the group consisting of a substituted or unsubstituted aromatic moiety of 6-60 carbons, a substituted or unsubstituted heteroaromatic moiety of 2-60 carbons, and combinations thereof; and

1 is an integer from 1 to 100,000, m is an integer from 0 to 100,000, and n is an integer from 1 to 100,000.

In addition, the present invention provides an electroluminescent device having at least one layer comprising the electroluminescent polymer between an anode and a cathode, in which the layer is an interlayer, a hole transport layer, a light emitting layer, an electron transport layer or a hole blocking layer.

### BRIEF DESCRIPTION OF THE DRAWING

FIG. 1 is a schematic cross-sectional view showing the structure of a conventional organic electroluminescent device comprising substrate/anode/hole transport layer/light emitting layer/electron transport layer/cathode;

FIG. 2 is a schematic cross-sectional view showing the structure of an electroluminescent device, according to an embodiment of the present invention;

FIG. 3 is a schematic cross-sectional view showing the structure of an electroluminescent device, according to another embodiment of the present invention;

FIG. 4 is a view schematically showing compound synthesis reactions according to Preparative Examples 1-3 of the present invention;

FIG. 5 is an ¹H-NMR spectrum of a compound (3) prepared according to Preparative Example 3 of the present invention;

FIG. 6 is an ¹H-NMR spectrum of the electroluminescent polymer represented by Formula 2, according to the present invention;

FIG. 7 is an electroluminescence spectrum of the electroluminescent device manufactured in Example 4 of the present invention;

FIG. 8 is an electroluminescence spectrum of the electroluminescent device manufactured in Example 6 of the present invention; and

FIG. 9 is a curve showing luminance varying with voltage of the electroluminescent device manufactured in Example 5 of the present invention.

### DETAILED DESCRIPTION OF THE INVENTION

Hereinafter, a detailed description will be given of the embodiments of the present invention, with reference to the accompanying drawings.

The present invention provides an electroluminescent polymer containing a 9-fluoren-2-yl-9-aryl-2,7-fluorenyl unit, which is usable as a host material for highly pure blue, green and red luminescence and has high solubility, high heat stability and high quantum efficiency, and an electroluminescent device manufactured using the electroluminescent polymer.

The electroluminescent polymer of the present invention, which is a material having excellent heat stability, light stability, solubility and film formability and high quantum efficiency, is characterized in that a fluorenyl group, which is a bulky substituent, is introduced at a 9-position of fluorene as a main chain, whereby the substituent has the same structure as the main chain. Therefore, the arrangement of the main chain and the substituent becomes random, and also, intermolecular excimer formation by the substituent is inhibited, thus preventing aggregation and/or excimer formation, which are the biggest problems encountered with polyfluorene-based polymers. Moreover, intramolecular or intermolecular energy transfer to the main chain from the substituent group having a short wavelength can be realized.

Further, the 9-position of fluorene used as the main chain serves to control rotation and vibronic modes using the bulky fluorenyl substituent to drastically reduce nonradiative decay. Therefore, the organic electroluminescent polymer of the present invention exhibits high color purity, high luminance and high efficiency.

According to the present invention, the electroluminescent polymer having a 9-fluoren-2-yl-9-aryl-2,7-fluorenyl unit is represented by the following Formula 1:

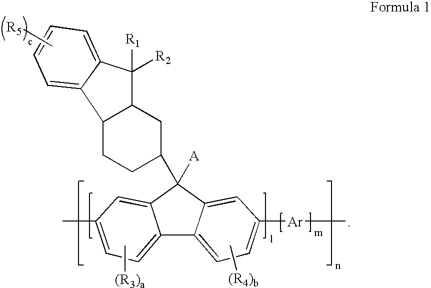

In Formula 1, R₁ and R₂ are the same or different, each being a linear or branched alkyl group of 1-20 carbons; an aryl group which is unsubstituted or substituted with at least one substituent group selected from the group consisting of linear or branched alkyl and alkoxy groups of 1-20 carbons; a linear or branched alkyl group of 1-20 carbons having at least one hetero-atom selected from the group consisting of F, S, N, O, P and Si; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si; a substituted or unsubstituted trialkylsilyl group of 3-40 carbons; a substituted or unsubstituted arylsilyl group of 3-40 carbons; a substituted or unsubstituted carbazole group of 12-60 carbons; a substituted or unsubstituted phenothiazine group of 6-60 carbons; or a substituted or unsubstituted arylamine group of 6-60 carbons.

R₃, R₄ and R₅ are the same or different, each being hydrogen; a linear or branched alkyl or alkoxy group of 1-20 carbons; an aryl group which is unsubstituted or substituted with at least one substituent group selected from the group consisting of linear or branched alkyl and alkoxy groups of 1-20 carbons; a linear or branched alkyl or alkoxy group of 1-20 carbons having at least one hetero-atom selected from the group consisting of F, S, N, O, P and Si; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si; a substituted or unsubstituted trialkylsilyl group of 3-40 carbons; a substituted or unsubstituted arylsilyl group of 3-40 carbons; a substituted or unsubstituted carbazole group of 12-60 carbons; a substituted or unsubstituted phenothiazine group of 6-60 carbons; or a substituted or unsubstituted arylamine group of 6-60 carbons.

Integers a, b and c are the same or different, each being an integer from 1 to 3.

A is an aryl group which is unsubstituted or substituted with at least one substituent group selected from the group consisting of linear or branched alkyl and alkoxy groups of 1-20 carbons; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; or an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si.

Ar is selected from the group consisting of a substituted or unsubstituted aromatic moiety of 6-60 carbons, a substituted or unsubstituted heteroaromatic moiety of 2-60 carbons, and combinations thereof; and

1 is an integer from 1 to 100,000, m is an integer from 0 to 100,000, and n is an integer from 1 to 100,000.

In accordance with the present invention, it is preferred that R₁ and R₂ be the same or different, each being selected from the following group:

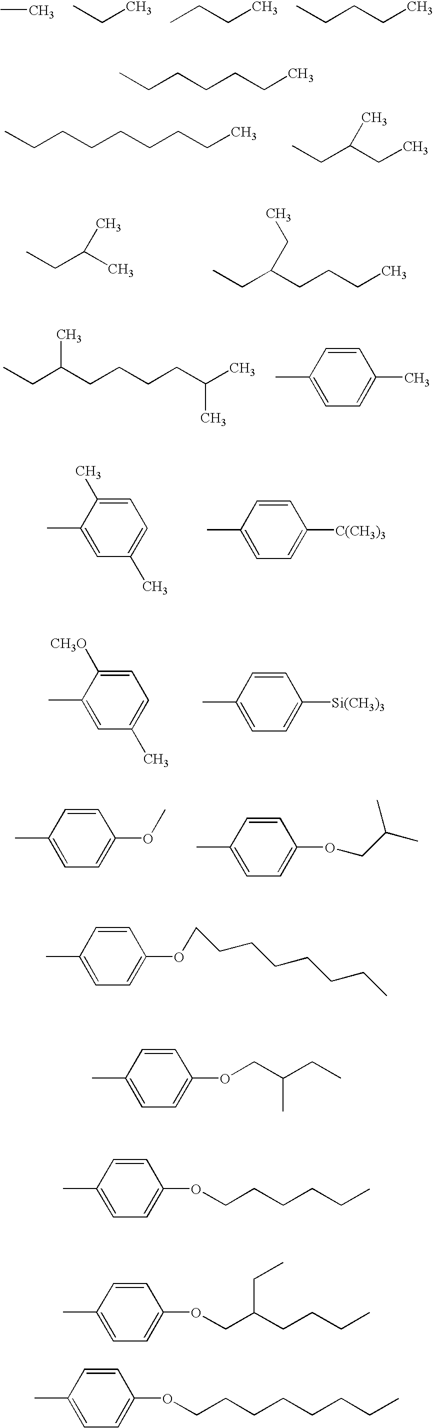

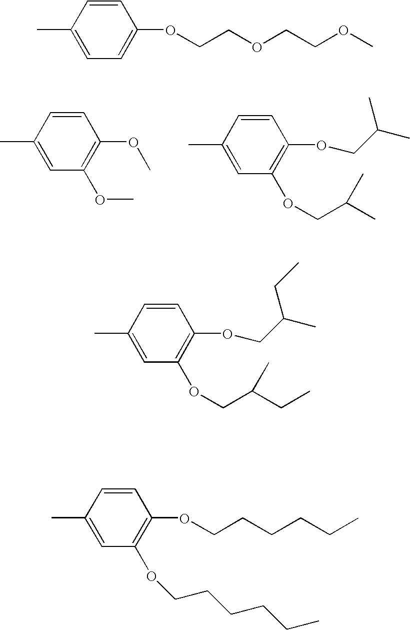

Further, it is preferred that R₃ and R₄ be the same or different, each being selected from the following group:

hydrogen,

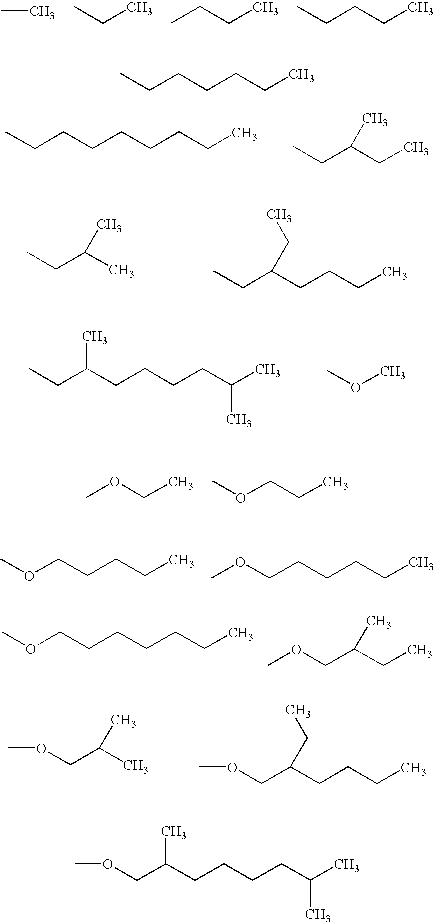

More preferably, R₃ and R₄ are each hydrogen.

Further, it is preferred that R₅ be selected from the following group:

hydrogen,

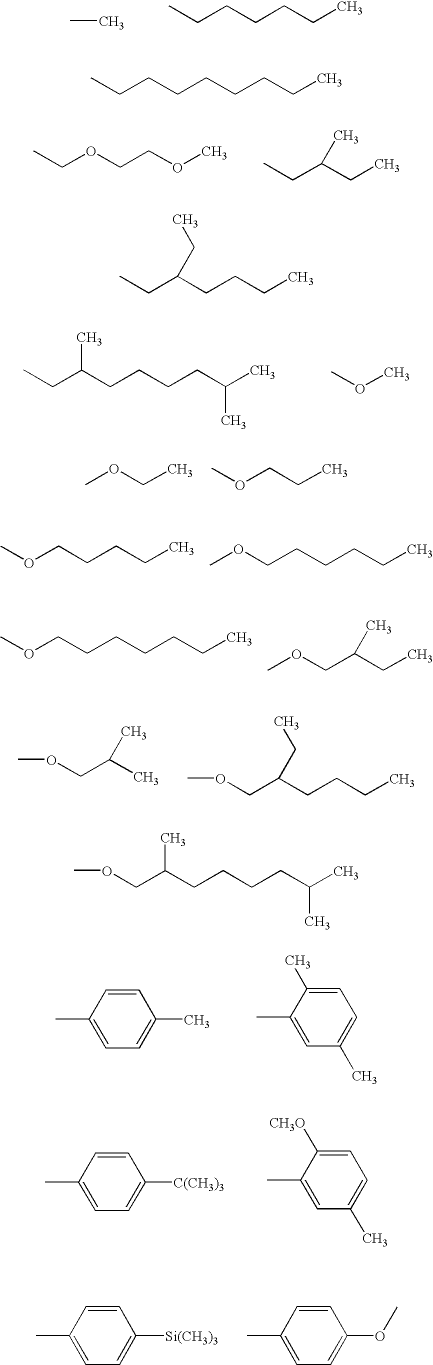

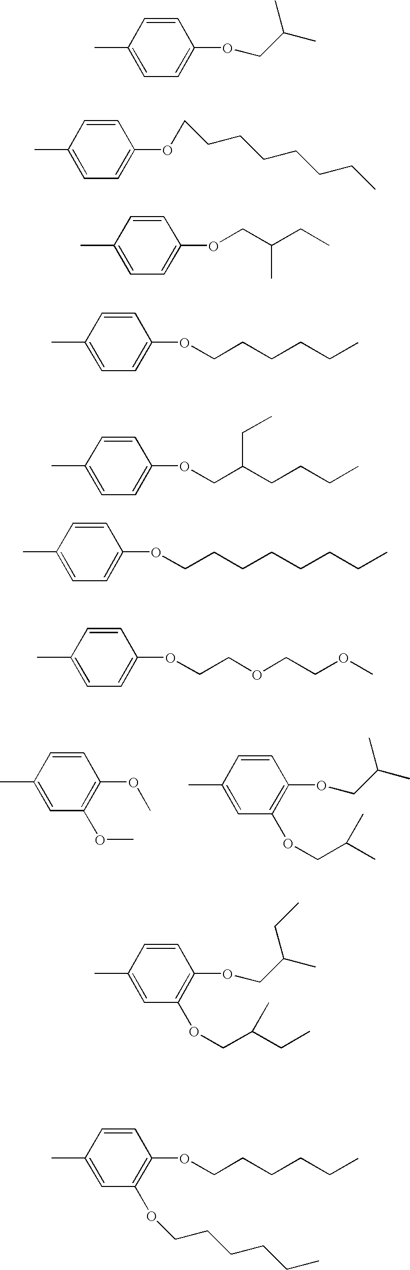

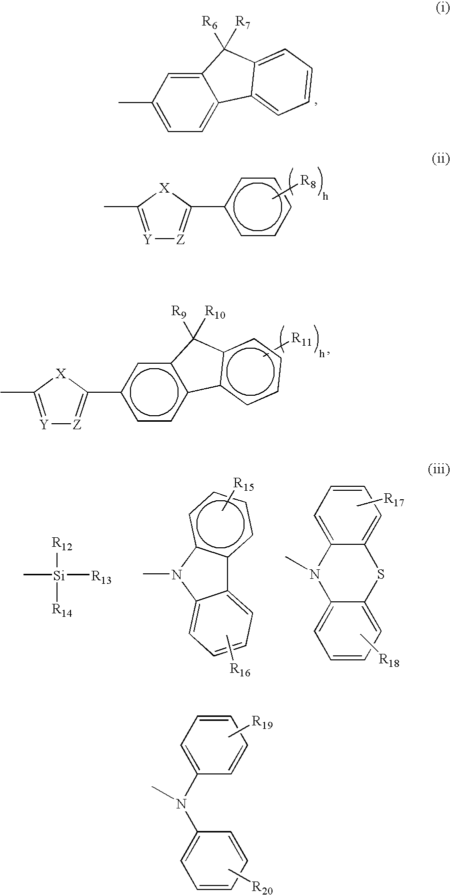

wherein

(i) R₆ and R₇ are the same or different, each being a linear or branched alkyl group of 1-20 carbons.

The above fluorenyl may be representatively selected from the following group:

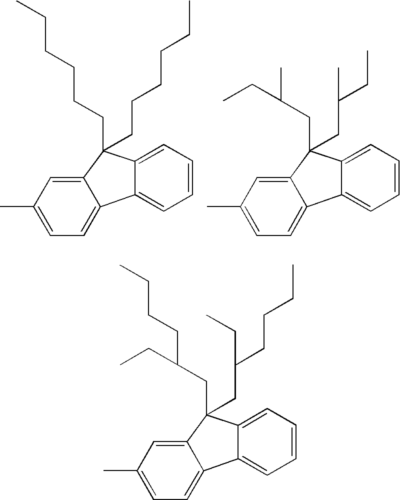

(ii) R₈ is hydrogen or a linear or branched alkyl, alkoxy or trialkylsilyl group of 1-20 carbons;

R₉ and R₁₀ are the same or different, each being a linear or branched alkyl group of 1-20 carbons, and R₁₁ is hydrogen or a linear or branched alkyl, alkoxy or trialkylsilyl group of 1-20 carbons;

X is O or S, and Y and Z are each N; and h and i are the same or different, each being an integer from 1 to 3.

The above aryl having a heterocyclic moiety may be representatively selected from the following group:

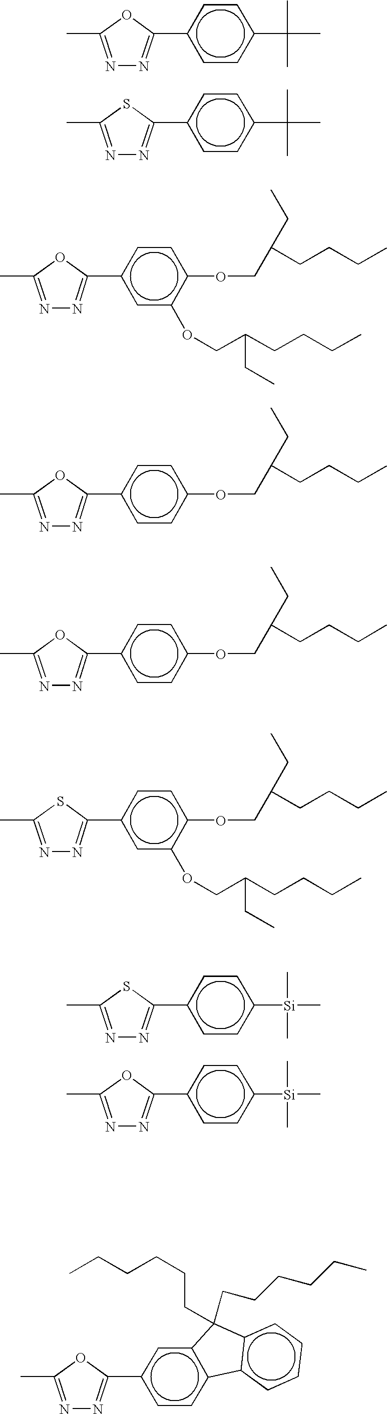

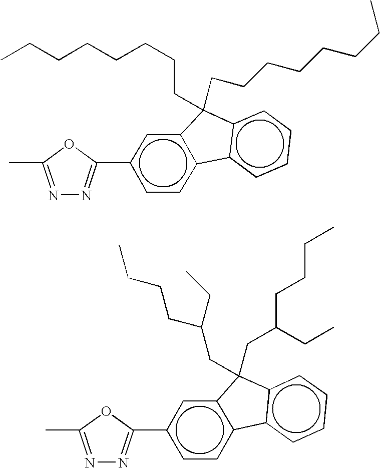

and

(iii) R₁₂, R₁₃ and R₁₄ are the same or different, each being a linear or branched alkyl or alkoxy group of 1-20 carbons; or an aryl group which is unsubstituted or substituted with at least one substituent group selected from the group consisting of linear or branched alkyl and alkoxy groups of 1-20 carbons; and

R₁₅, R₁₆, R₁₇, R₁₈, R₁₉ and R₂₀ are the same or different, each being hydrogen; a linear or branched alkyl or alkoxy group of 1-20 carbons; or an aryl group which is unsubstituted or substituted with at least one substituent group selected from the group consisting of linear or branched alkyl and alkoxy groups of 1-20 carbons.

The above silyl, carbazole, phenothiazine and arylamine may be representatively selected from the following group:

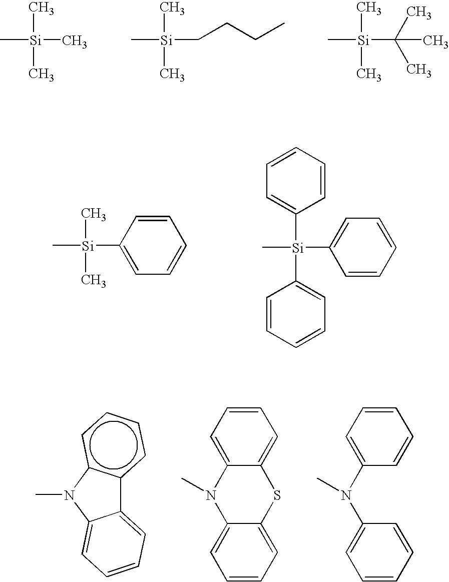

More preferably, R₅ is hydrogen.

Further, A may be preferably represented by the following group:

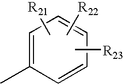

wherein R₂₁, R₂₂ and R₂₃ are the same or different, each being hydrogen; a linear or branched alkyl or alkoxy group of 1-20 carbons; or a linear or branched alkyl or alkoxy group of 1-20 carbons having at least one hetero-atom selected from the group consisting of F, S, N, O, P and Si.

The above A may be selected from the following group:

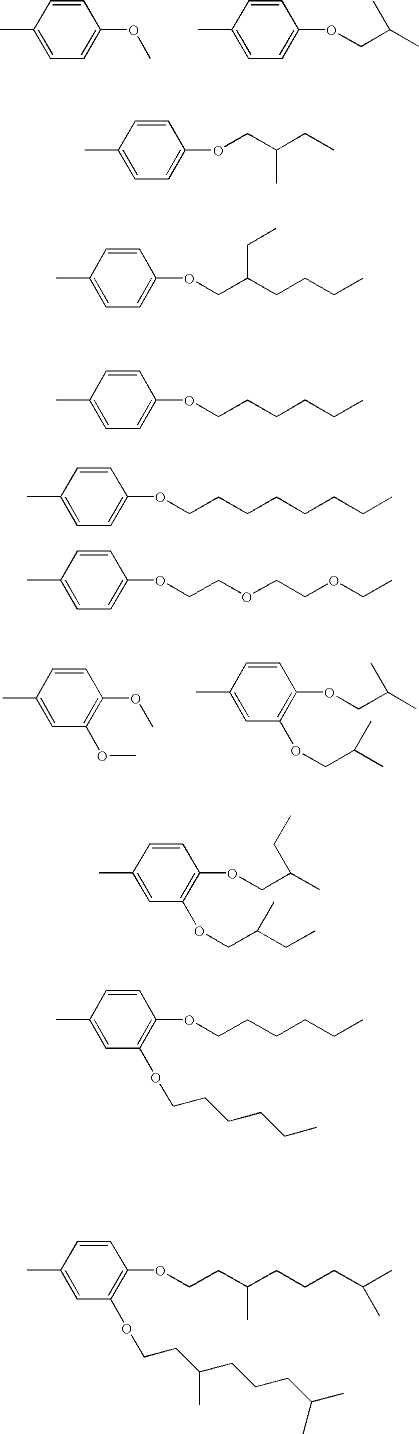

In accordance with the present invention, it is preferred that Ar be selected from the following group:

(i) a substituted or unsubstituted arylene group of 6-60 carbons;

(ii) a substituted or unsubstituted heterocyclic arylene group of 2-60 carbons in which at least one hetero-atom selected from the group consisting of N, S, O, P and Si is incorporated in an aromatic ring;

(iii) a substituted or unsubstituted arylenevinylene group of 6-60 carbons;

(iv) a substituted or unsubstituted arylamine group of 6-60 carbons;

(v) a substituted or unsubstituted carbazole group of 12-60 carbons; and

(vi) combinations thereof,

in which Ar may have a substituent group, such as a linear or branched alkyl or alkoxy group of 1-20 carbons, an aryl group which is unsubstituted or substituted with at least one substituent group selected from the group consisting of linear or branched alkyl and alkoxy groups of 1-20 carbons, a cyano group (—CN), or a silyl group.

More specifically,

(i) when Ar is a phenylene group or fluorenyl group, among the substituted or unsubstituted arylene group of 6-60 carbons, it may be selected from the following group:

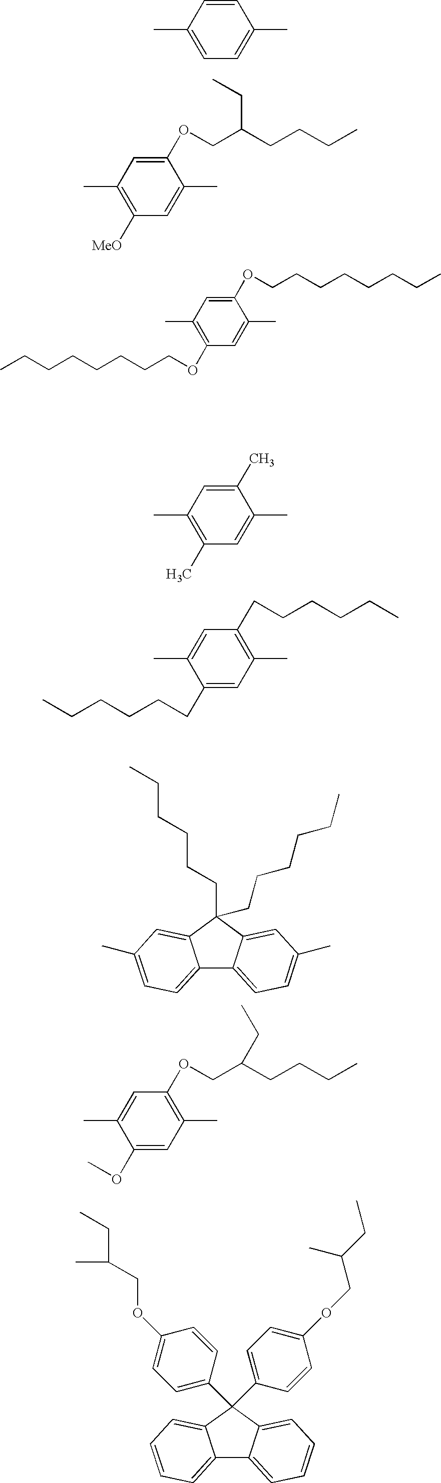

(ii) when Ar is a substituted or unsubstituted heterocyclic arylene group of 2-60 carbons, it may be selected from the following group:

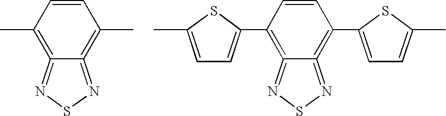

(iii) when Ar is a substituted or unsubstituted arylenevinylene group of 6-60 carbons, it may be selected from the following group:

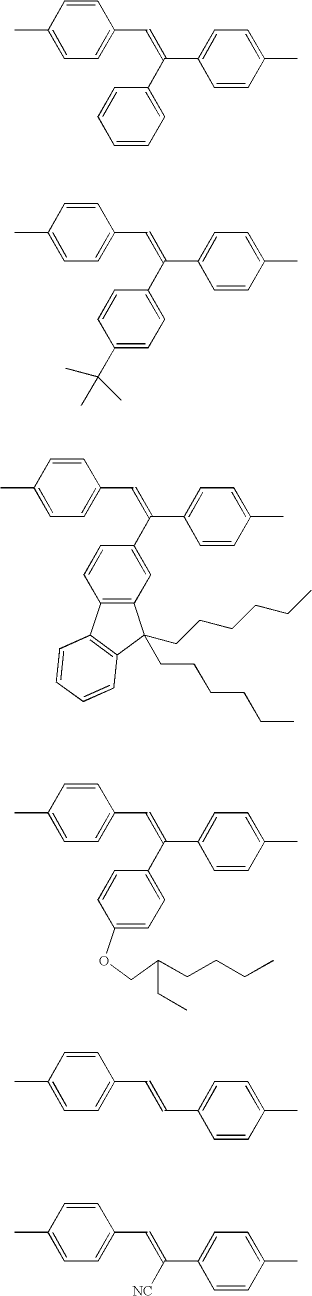

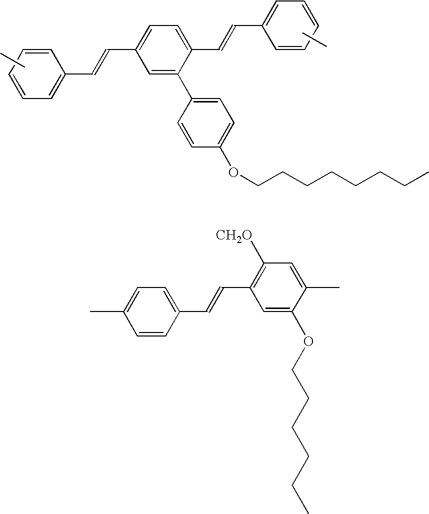

(iv) when Ar is a substituted or unsubstituted arylamine group of 6-60 carbons, it may be selected from the following group:

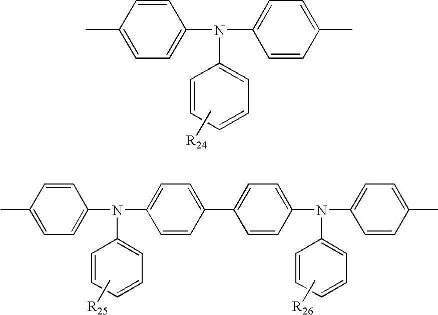

wherein R₂₄, R₂₅ and R₂₆ are the same or different, each being hydrogen; a linear or branched alkyl or alkoxy group of 1-20 carbons; or an aryl group which is unsubstituted or substituted with at least one substituent group selected from the group consisting of linear or branched alkyl and alkoxy groups of 1-20 carbons,

Ar being preferably selected from the following group:

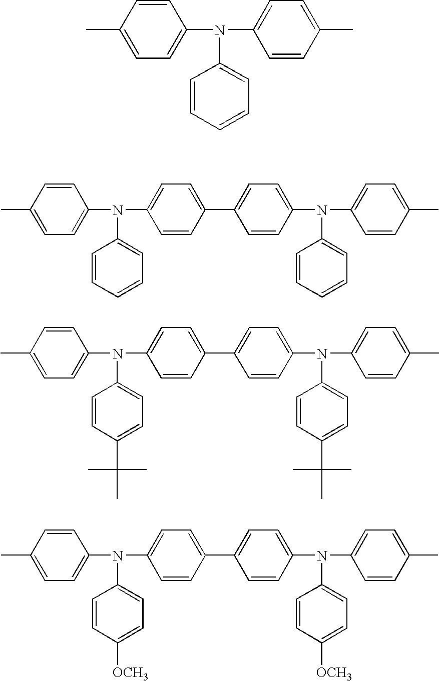

and

(v) when Ar is a substituted or unsubstituted carbazole group of 12-60 carbons, it may be selected from the following group:

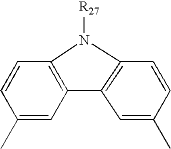

wherein R₂₇ is a linear or branched alkyl or alkoxy group of 1-20 carbons; or an aryl group which is unsubstituted or substituted with at least one substituent group selected from the group consisting of linear or branched alkyl and alkoxy groups of 1-20 carbons.

Further, when Ar is (iv) a substituted or unsubstituted arylamine group of 6-60 carbons, it is preferably present in an amount of about 5-15 mol % in the electroluminescent polymer.

The preparation of the electroluminescent polymer in an embodiment of the present invention includes, for example, preparing monomers through alkylation, bromization, Grignard reaction, etc., and then preparing organic electroluminescent polymers through a C—C coupling reaction such as a Yamamoto coupling reaction or a Suzuki coupling reaction. The resultant polymers have a number average molecular weight of 700-10,000,000, and a molecular weight distribution of 1-100.

The organic electroluminescent polymer of the present invention can be applied as a host for blue, green and red luminescence having excellent heat stability, oxidation stability and solubility, and exhibiting low interaction of molecules, easy energy transfer, and high luminescence efficiency due to the suppression of vibronic mode.

According to the present invention, the organic electroluminescent polymer may be used as a material for forming an interlayer, a light emitting layer, a hole transport layer, and an electron transport layer or a hole blocking layer, disposed between one pair of electrodes in the electroluminescent device.

The electroluminescent device includes a basic structure of anode/light emitting layer/cathode, and optionally, further has an interlayer, a hole transport layer and an electron transport layer.

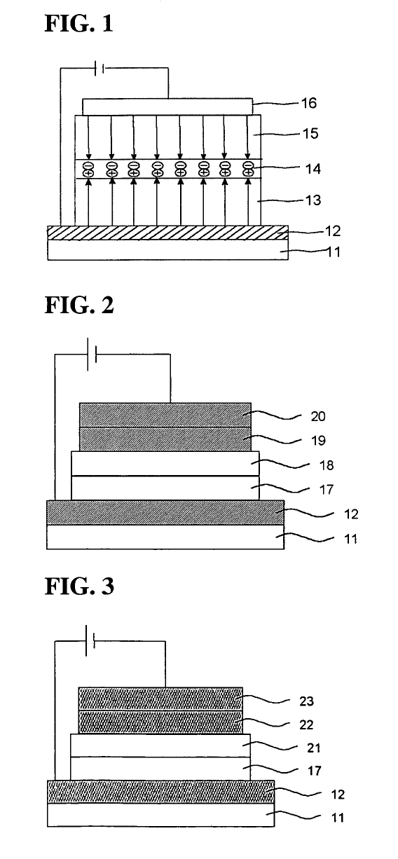

Referring to FIG. 1 which is a cross-sectional view showing a typical structure of an electroluminescent device comprising substrate/anode/hole transport layer/light emitting layer/electron transport layer/cathode, the electroluminescent device is, for example, fabricated using the organic electroluminescent polymer of the present invention as follows.

An upper surface of a substrate 11 is coated with an electrode material of an anode 12.

As the substrate 11, any substrate used for the conventional organic electroluminescent device is employed. Preferably, a glass substrate or a transparent plastic substrate having excellent transparency, surface flatness, easy handling and water resistance is useful.

Further, the electrode material for the anode 12 includes indium tin oxide (ITO), tin oxide (SnO₂), zinc oxide (ZnO), which are transparent and highly conductive.

Subsequently, a hole transport layer 13 may be formed on the anode 12 through vacuum deposition or sputtering, after which a light emitting layer 14 is formed through a solution coating process such as spin coating or inkjet printing. Also, an electron transport layer 15 is formed on the light emitting layer 14, before forming a cathode 16. As such, the light emitting layer 14 has a thickness ranging from about 5 nm to about 1 μm, and preferably from about 10 to about 500 nm. Each of the hole transport layer 13 and the electron transport layer 15 is about 10-10,000 Å thick.

The electron transport layer 15 is obtained by using the conventional electron transport layer forming material or by subjecting the compound represented by Formula 1 to vacuum deposition, sputtering, spin coating or inkjet printing.

The hole transport layer 13 and the electron transport layer 15 function to efficiently transfer carriers to the luminescent polymer, thereby increasing luminescence efficiency in the luminescent polymer. Further, the material forming the hole transport layer 13 and the electron transport layer 15 is not particularly limited in the present invention. For example, the hole transport layer material includes PEDOT:PSS as poly(3,4-ethylenedioxy-thiophene) (PEDOT) doped with a poly(styrenesulfonic acid) (PSS) layer, and N,N′-bis(3-methylphenyl)-N,N-diphenyl-[1,1′-biphenyl]-4,4′-diamine (TPD), while the electron transport material includes aluminum trihydroxyquinoline (Alq₃), a 1,3,4-oxadiazole derivative PBD (2-(4-biphenylyl)-5-phenyl-1,3,4-oxadiazole), a quinoxaline derivative TPQ (1,3,4-tris[(3-phenyl-6-trifluoromethyl)quinoxaline-2-yl]benzene) and a triazole derivative.

In cases where the organic electroluminescent polymer is subjected to solution coating to form the layer, it may be blended with a polymer having conjugated double bonds such as polyphenylenevinylene and polyparaphenylene, as well as other fluorene-based polymers. As necessary, binder resins may be mixed for use. The binder resin is exemplified by polyvinylcarbazole, polycarbonate, polyester, polyarylate, polystyrene, acryl polymer, methacryl polymer, polybutyral, polyvinylacetal, diallylphthalate polymer, phenol resin, epoxy resin, silicone resin, polysulfone resin or urea resin. The resins may be used alone or in combinations thereof.

Optionally, a hole blocking layer made of LiF (lithium fluoride) is further formed through vacuum deposition so as to function to control a transfer rate of the hole in the light emitting layer 14 and increase combination efficiency between an electron and a hole.

Finally, an electrode material of a cathode 16 is applied on the electron transport layer 15.

The metal for forming the cathode 16 of low work function includes, for example, lithium (Li), magnesium (Mg), calcium (Ca), aluminum (Al), Al:Li, Ba:Li, and Ca:Li.

Structures of electroluminescent devices according to several embodiments are shown in FIGS. 2 and 3.

As seen in FIG. 2, the electroluminescent device according to an embodiment comprises a substrate 11, an anode 12, a 500 Å thick hole transport layer 17 formed of PEDOT:PSS, a 100-2000 Å thick light emitting layer 18 formed of the electroluminescent polymer of Formula 1, a 20 Å thick hole blocking layer 19 formed of LiF, and a 700 Å thick cathode 20 formed of Al.

As seen in FIG. 3, the electroluminescent device according to another embodiment comprises a substrate 11, an anode 12, a 500 Å thick hole transport layer 17 formed of PEDOT:PSS, a 100-2000 Å thick light emitting layer 21 formed of the electroluminescent polymer of Formula 1, and Ca:Al cathodes 22 and 23 being 500 Å and 1500 Å thick and formed of Ca and Al, respectively.

The electroluminescent device is fabricated to have the sequence of anode/interlayer/hole transport layer/light emitting layer/electron transport layer/cathode or the reverse, that is, cathode/electron transport layer/light emitting layer/hole transport layer/interlayer/anode.

In addition, the organic electroluminescent polymer is applied not only as the high molecular weight organic electroluminescent device material, but also as a light conversion material for a light diode or a semiconductor material for a polymer TFT (Thin Film Transistor).

According to the present invention, the organic electroluminescent polymer has the fluorenyl group, which is a bulky substituent, introduced at the 9-position of fluorene serving as the main chain. Thus, the substituent has the same structure as the main chain, whereby the random arrangement between the main chain and the substituent occurs. Further, intermolecular excimer formation by the substituent can be suppressed, thus preventing aggregation and/or excimer formation, which are regarded as the biggest problems in the field of polyfluorenes. Also, intramolecular or intermolecular energy transfer from the substituent group having a short wavelength to the main chain can be realized. By the substituted fluorenyl group introduced at the 9-position of the fluorene group as the main chain, rotation and vibronic modes are controlled, hence dramatically reducing nonradiative decay to exhibit high heat stability, light stability, solubility, film formability and quantum efficiency. Therefore, the organic electroluminescent polymer of the present invention and the organic electroluminescent device manufactured using the same can exhibit excellent color purity and luminance and high efficiency.

A better understanding of the present invention may be obtained in light of the following example which is set forth to illustrate, but is not to be construed to limit the present invention.

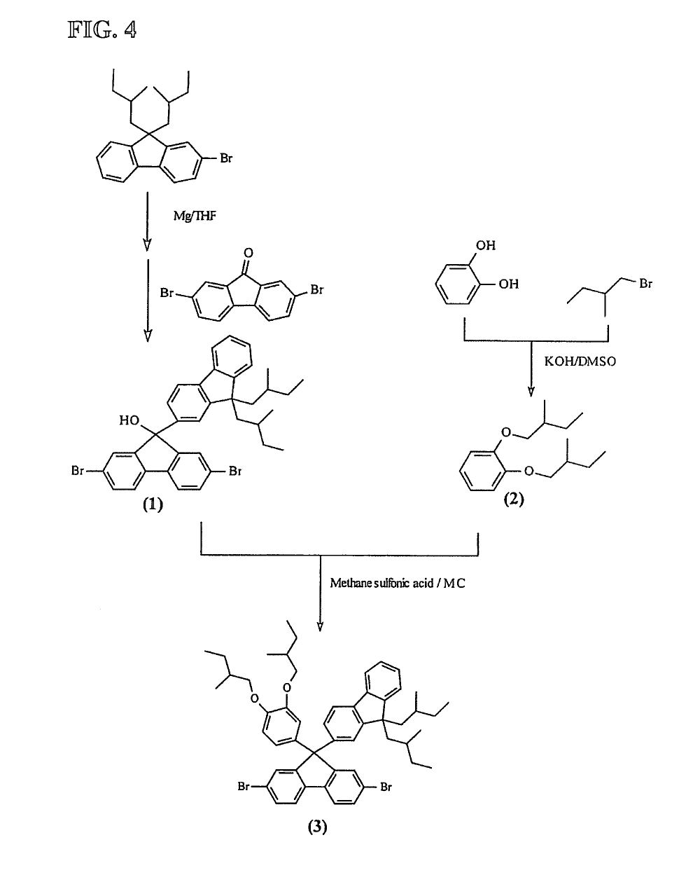

The following Preparative Examples 1-3 were conducted according to the reaction shown in FIG. 4.

### PREPARATIVE EXAMPLE 1

### Synthesis of (9-(9′,9′-di(2″-methyl)butylfluoren-2′-yl)-2,7-dibromofluoren-9-ol) (1)

In a 500 ml three-neck flask, 3.3 g (137 mmol) of Mg was slowly added dropwise with 44 g (114 mmol) of 9,9-di(2′-methyl)butyl-2-bromofluorene in 200 ml of THF, to prepare a Grignard reagent. After the temperature of a reaction bath was decreased to −40° C. or less, 30 g (91 mmol) of 2,7-dibromofluorenone was added to the reaction bath in a nitrogen atmosphere. The temperature was gradually increased to room temperature, followed by stirring for 10 hours. The resulting reaction solution was poured into water, after which an extraction was performed using diethyl ether. The solvent was evaporated using a rotary evaporator. Column chromatography separation resulted in 43 g (67 mmol, 73%) of (9-(9′,9′-di(2″-methyl)butylfluoren-2′-yl)-2,7-dibromofluoren-9-ol) (1).

### PREPARATIVE EXAMPLE 2

### Synthesis of (1,2-di(2-methyl)butyloxy benzene) (2)

In a 500 ml round-bottom flask, 20 g (91 mmol) of compound cathechol and 107 g (436 mmol) of 2-methyl butyl p-toluene sulfonate were dissolved in 200 ml of DMSO. The reaction solution was slowly added with 53 g (473 mmol) of potassium t-butoxide (t-BuOK), and was then allowed to react at 70° C. for 12 hours. The resulting reaction solution was poured into 500 ml of water, after which an extraction was performed using methylene chloride. The solvent was evaporated using a rotary evaporator. Column chromatography separation using a solvent mixture comprising hexane and ethyl acetate resulted in 37 g (148 mmol, 81%) of 1,2-di(2-methyl)butyloxy benzene (2).

### PREPARATIVE EXAMPLE 3

### Synthesis of 2,7-dibromo-9-(9′,9′-di(2′″-metylbutyl)fluoren-2′-yl)-9-(3″,4″-di(2″″-methyl)butyloxyphenyl) fluorene (3)

In a 2 L round-bottom flask, 50 g (78 mmol) of (9-(9′,9′-di(2″-methyl)butylfluoren-2′-yl)-2,7-dibromofluoren-9-ol) (1) and 23.3 g (93 mmol) of (1,2-di(2-methyl)butyloxy benzene) (2) were dissolved in 1000 ml of dichloromethane, and the temperature was decreased to 0° C. The reaction solution was slowly added with a solution of 7.5 g (78 mmol) of methane sulfonic acid in 100 ml of dichloromethane with stirring, followed by further stirring for 2 hours. The resulting reaction solution was poured into water, after which an extraction was performed using diethyl ether. The solvent was evaporated using a rotary evaporator. Column chromatography separation resulted in 67 g (65 mmol, 84%) of 2,7-dibromo-9-(9′,9′-di(2′″-metylbutyl)fluoren-2′-yl)-9-(3″,4″-di(2″″-methyl)butyloxyphenyl) fluorene (3).

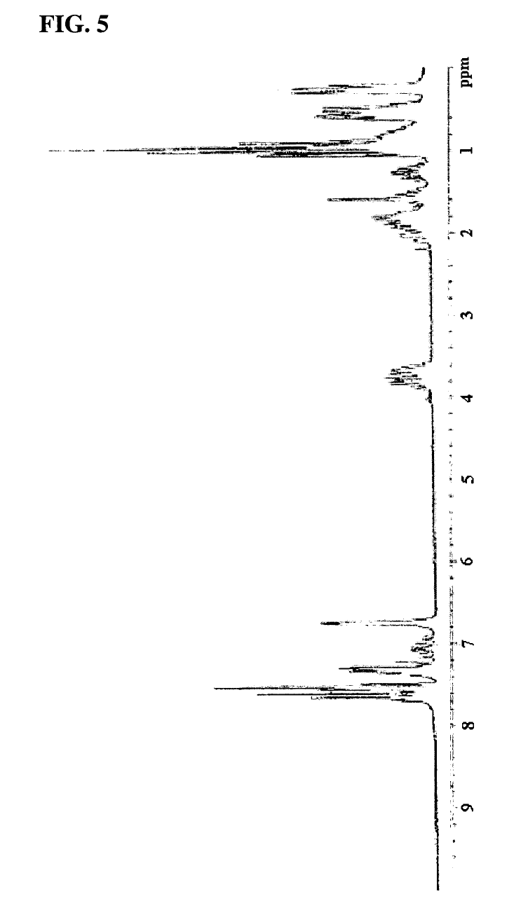

The ¹H-NMR spectrum of 2,7-dibromo-9-(9′,9′-di(2′″-metylbutyl)fluoren-2′-yl)-9-(3″,4″-di(2″″-methyl)butyloxyphenyl) fluorene (3) is shown in FIG. 5.

### EXAMPLE 1

### Synthesis of Poly(9-(9′,9′-di(2′″-metylbutyl)fluoren-2′-yl)-9-(3″,4″-di(2″″-methyl) butyloxyphenyl)-2,7-fluorenyl) of Formula 2

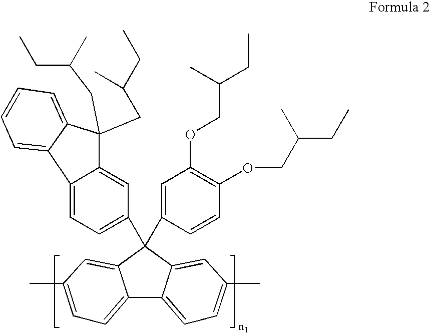

wherein n₁ is an integer from 1 to 100,000.

In a 500 ml Schrenk flask, 6 g (9.25 mmol) of compound (3) was dissolved in 60 ml of toluene degassed with nitrogen, and then stored in a nitrogen atmosphere. As catalysts, 5.780 g (21.01 mmol) of Ni(COD)₂, 1.45 g (13.42 mmol) of 1,4-cyclooctadiene (COD), and 3.224 g (21.28 mmol) of dipyridyl were placed into the Schrenk flask in a nitrogen atmosphere, to which 240 ml of toluene degassed with nitrogen and 60 ml of DMF were added, followed by stirring at 80° C. for 30 min. The monomer solution thus prepared was added to the reaction vessel and the reaction was allowed to occur for 150 hours. The resultant reaction solution was mixed with 2 ml of bromobenzene, followed by reaction for 24 hours and then terminal completion. Thereafter, the reaction solution was added to 1500 ml of a solution of hydrochloric acid (35 wt %):acetone:ethanol=1:1:1, to remove an unreacted catalyst and precipitate a polymer. The polymer was filtered and dissolved in chloroform, followed by filtration with celite to remove the remaining catalyst. Concentration, reprecipitation in methanol and washing with Soxlet for 24 hours were performed. Yield: 63%, molecular weight: Mw=166,000 and Mn=80,000, and PDI(polydispersity)=2.08.

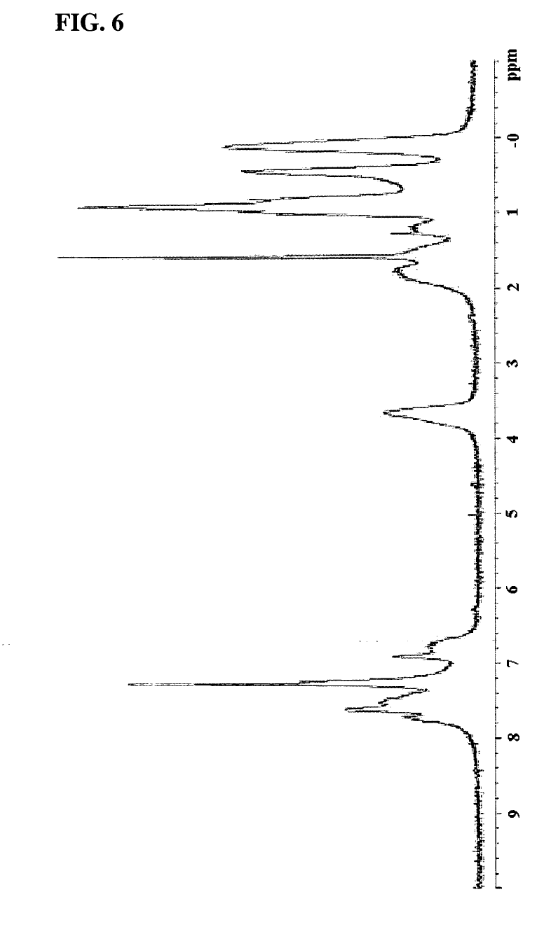

The ¹H-NMR spectrum of the electroluminescent polymer thus prepared is shown in FIG. 6.

### EXAMPLE 2

### Synthesis of Polymer of Formula 3

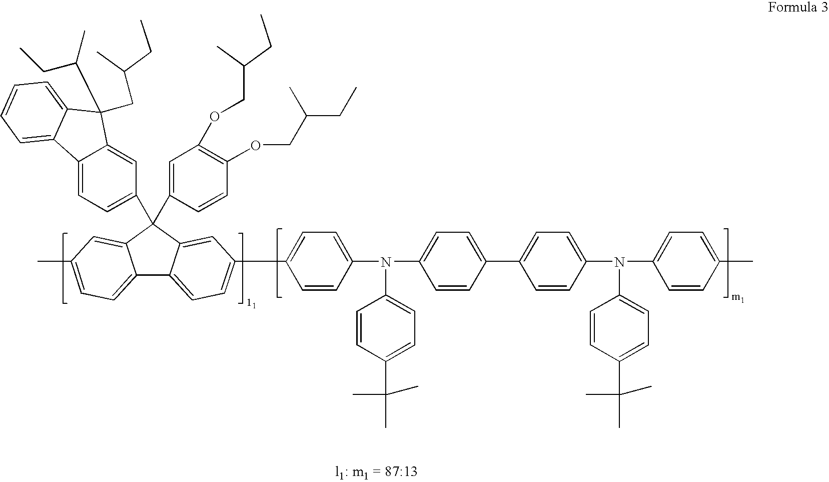

The polymer of Formula 3 was synthesized according to the following Reaction 1:

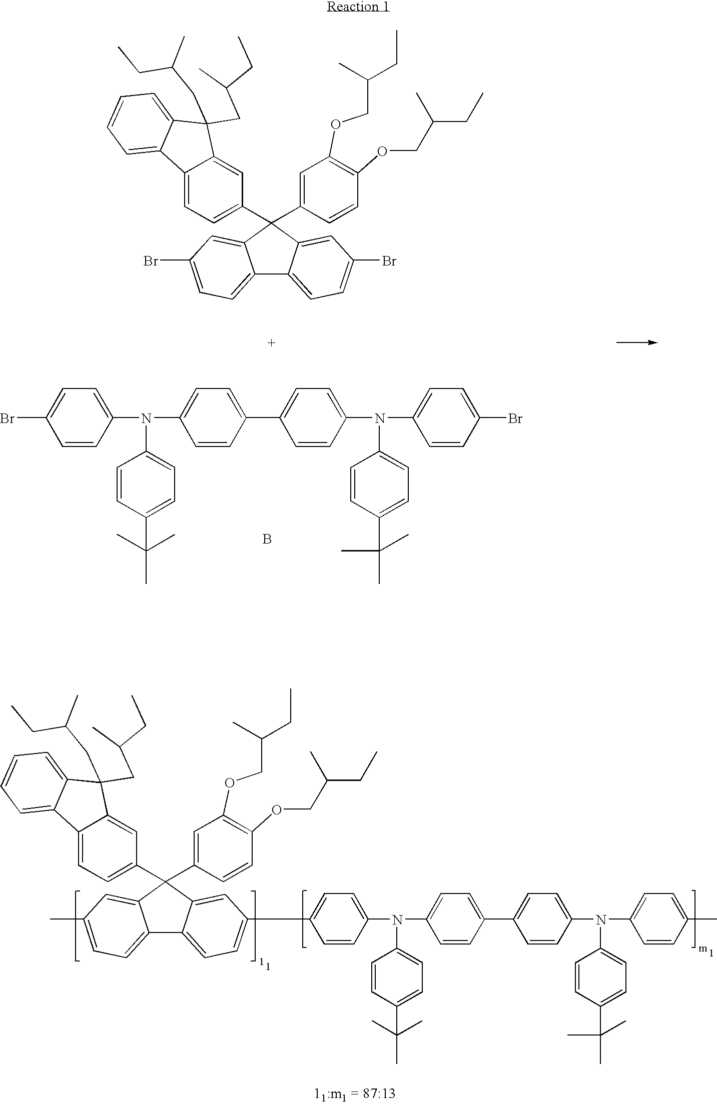

wherein l₁ is an integer from 1 to 100,000 and m₁ is an integer from 1 to 100,000.

A polymer was synthesized in the same manner as in Example 1, with the exception that 87 mol % of the compound (3) and 13 mol % of the compound B were used as monomers. Mw=230,000, Mn=87,000, PDI=2.64.

### EXAMPLE 3

### Synthesis of Polymer of Formula 4

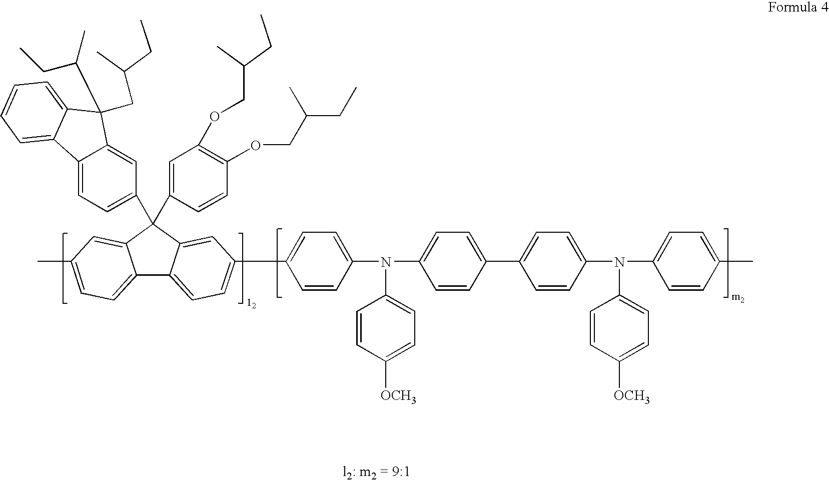

The polymer of Formula 4 was synthesized according to the following Reaction 2:

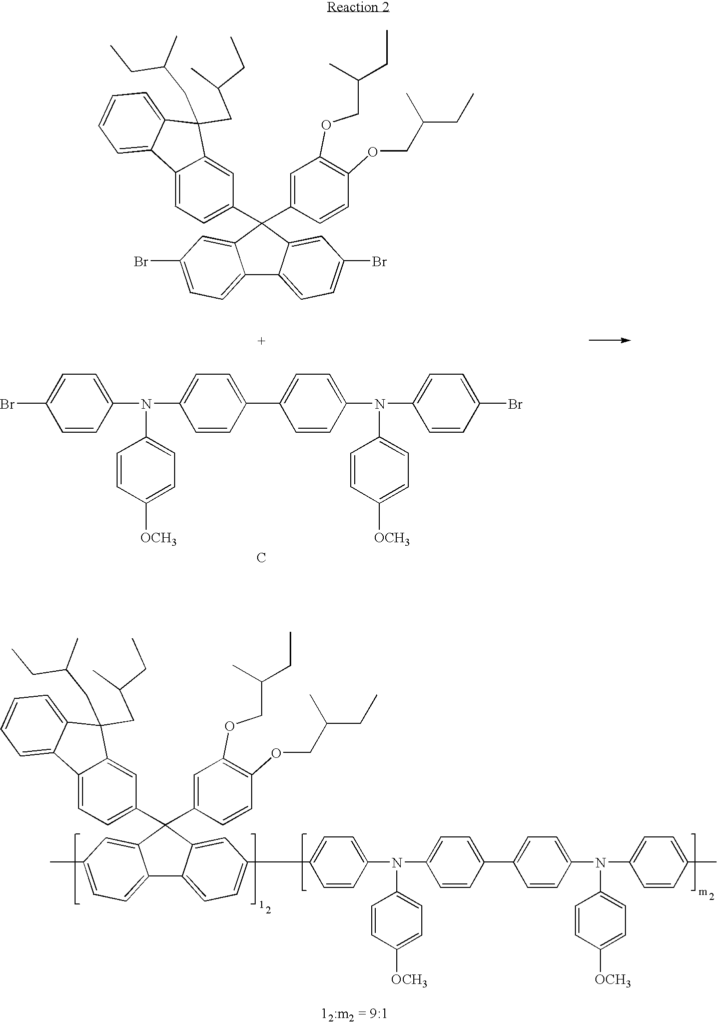

wherein l₂ is an integer from 1 to 100,000 and m₂ is an integer from 1 to 100,000.

A polymer was synthesized in the same manner as in Example 1, with the exception that 90 mol % of the compound (3) and 10 mol % of the compound C were used as monomers. Mw=218,000, Mn=77,000, PDI=2.83.

### EXAMPLES 4-6

Fabrication of Electroluminescent Device

On a glass substrate, an ITO (indium tin oxide) electrode was formed. Then, polymers for electroluminescent devices as given in Table 1, below, were applied on the ITO electrode through spin coating, to form light emitting layers being 400-1500 Å thick. Al:Li was vacuum deposited on the light emitting layer to form a 100-1200 Å thick aluminum lithium electrode, thereby fabricating an organic electroluminescent device, luminescence properties of which were then measured. The results are provided in Table 1, below.

TABLE 1

| | Light | | | Max. | |
|---|---|---|---|---|---|
| Ex. | Emitting | Driving | EL λₘₐₓ | Efficiency | Color Coordinate |
| No. | Layer | Voltage (V) | (nm) | (cd/A) | System (x, y) |
| 4 | Formula 2 | 4.5 | 422 | 0.14 | 0.147, 0.050 |
| 5 | Formula 3 | 3.5 | 448 | 1.45 | 0.149, 0.119 |
| 6 | Formula 4 | 4.0 | 460 | 2.51 | 0.152, 0.133 |

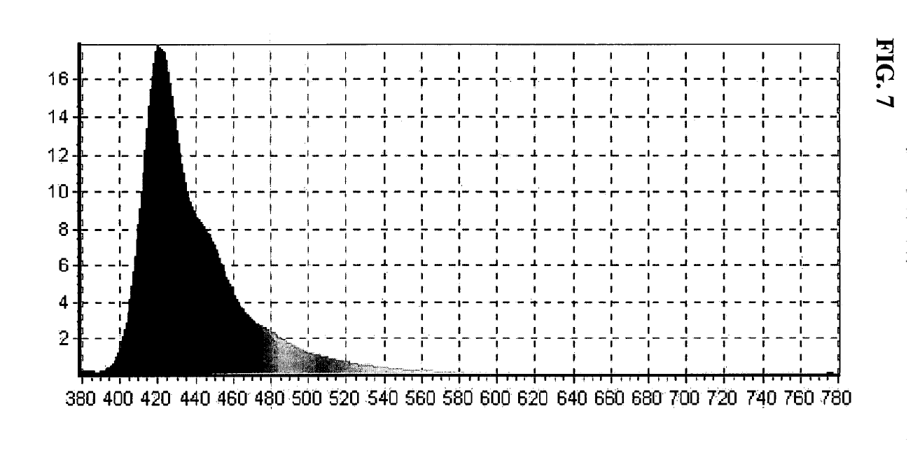

FIG. 7 shows the electroluminescence spectrum of the electroluminescent device (Example 4) manufactured using the electroluminescent polymer represented by Formula 2 as a material for light emitting layer, which has a maximum peak of 422 nm corresponding to a blue luminescent region. In addition, the peak due to excimers, which is generally shown near 530 nm in the electroluminescence spectrum of polyfluorene-based polymers, is not observed in the present invention, and the maximum efficiency is measured to be 0.14 cd/m², which is regarded as high. Such results are based on the suppression of intermolecular or intramolecular excimer formation and aggregation by the fluorenyl group substituted at the 9-position of fluorene, the inhibition of rotation and vibronic modes by the bulky fluorenyl group, and energy transfer from the fluorenyl group substituted at a side chain having a large bandgap to a main chain having a smaller bandgap. As is apparent from Example 4 of Table 1, the above device has a color coordinate system of x, y=0.147, 0.050 and thus can emit a greater amount of UV light than NTSC standard blue (x, y=0.16, 0.08).

Thereby, the compound (2) is confirmed to be a host material suitable for the preparation of electroluminescent polymers of all of luminescent regions including highly pure blue, green, yellow and red luminescence.

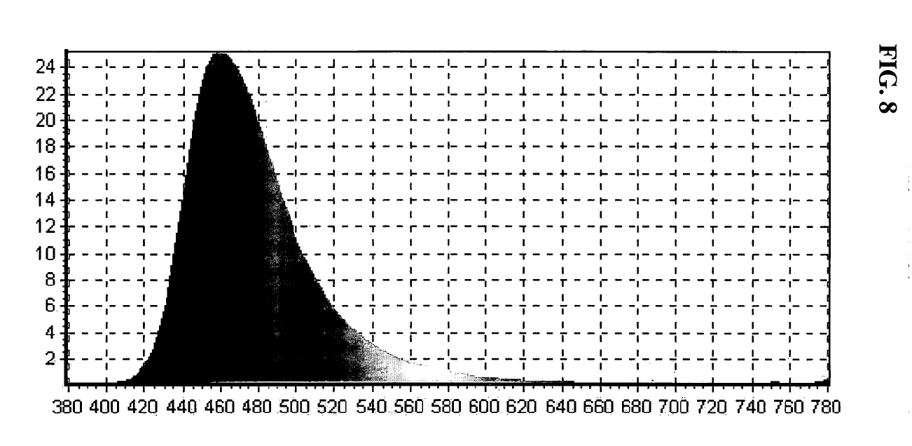

FIG. 8 shows the electroluminescence spectrum of the electroluminescent device (Example 6) manufactured using the electroluminescent polymer represented by Formula 4, which has a maximum peak of 460 nm corresponding to a blue luminescent region. Near the above peak wavelength, the above device has a color coordinate system (x, y=0.152, 0.133) superior to that of a conventional luminescent device using an alkoxyphenyl-substituted diamine derivative as a blue luminescent polymer material. In addition, the excimer peak, which is generally shown near 530 nm in the electroluminescence spectrum of polyfluorene-based polymers, is not observed. The maximum efficiency is measured to be 1.45 cd/m², which is regarded as high.

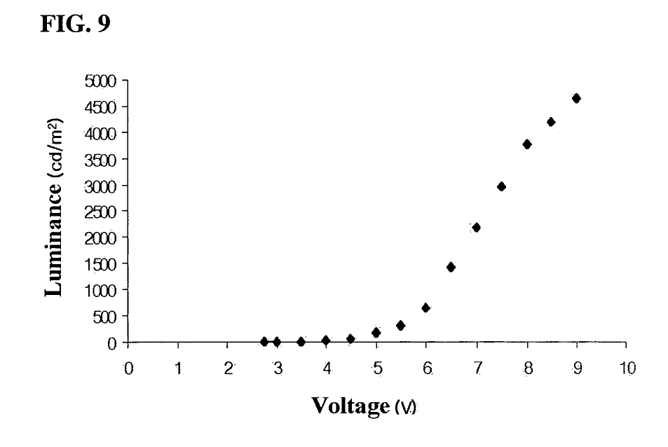

FIG. 9 shows a luminance curve varying with voltage of the electroluminescent device (Example 5) manufactured using the electroluminescent polymer represented by Formula 3. As shown in this drawing, the driving initiation voltage is as low as 3.5 V, despite the use of the polymer of Formula 3 having the bulky substituent. Further, the luminance is stably increased in proportion to an increase in driving voltage. Therefore, the formation of a film through spin coating leads to excellent luminescence properties.

In this way, the electroluminescent devices, which are manufactured in Examples 5 and 6 using the electroluminescent polymers resulting from polymerization of the compound (3) and the amine monomers to improve hole transfer and injection properties, exhibit excellent properties, that is, low driving voltage, very high luminescence efficiency, and luminescence in the blue luminescent region by virtue of good color purity thereof even with the use of TPD-based amine.

As described above, the present invention provides an electroluminescent polymer having a 9-fluoren-2-yl-9-aryl-2,7-fluorenyl unit and an electroluminescent device manufactured using the same. The electroluminescent polymer of the present invention has superior heat stability, high luminescence efficiency and high solubility, and serves to minimize the interaction of molecules. Further, the above polymer can alleviate the disadvantages of conventional polyfluorene-based polymers, and be used as a host material for blue, green and red luminescence of the electroluminescent device, thus manifesting superior luminescence properties.

Although the embodiments of the present invention have been disclosed for illustrative purposes, those skilled in the art will appreciate that various modifications, additions and substitutions are possible, without departing from the scope and spirit of the invention as disclosed in the accompanying claims.

1. An electroluminescent polymer represented by: 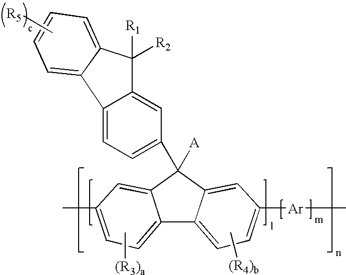
wherein R₁ and R₂ are independently a linear or branched alkyl group having 1-20 carbons; an aryl group which is unsubstituted or substituted with at least one substituent group selected from the group consisting of linear or branched alkyl and alkoxy groups having 1-20 carbons; a linear or branched alkyl group having 1-20 carbons and at least one hetero-atom selected from the group consisting of F, S, N, O, P and Si; an aryl group which is substituted with at least one substituent group selected from the group consisting of linear or branched alkyl and alkoxy groups having 1-20 carbons and at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups having 1-20 carbons; an aryl group having a heterocyclic moiety of 2-24 carbons which is substituted with at least one substituent group selected from the group consisting of linear or branched alkyl and alkoxy groups having 1-20 carbons having at least one hetero-atom selected from the group consisting of F, S, N, O, P and Si; a substituted or unsubstituted trialkylsilyl group having 3-40 carbons; a substituted or unsubstituted arylsilyl group having 3-40 carbons; a substituted or unsubstituted carbazole group having 12-60 carbons; a substituted or unsubstituted phenothiazine group having 6-60 carbons; or a substituted or unsubstituted arylamine group having 6-60 carbons;
R₃, R₄ and R₅ are independently hydrogen; a linear or branched alkyl or alkoxy group having 1-20 carbons; an aryl group which is unsubstituted or substituted with at least one substituent group selected from the group consisting of linear or branched alkyl and alkoxy groups having 1-20 carbons; a linear or branched alkyl or alkoxy group having 1-20 carbons and at least one hetero-atom selected from the group consisting of F, S, N, O, P and Si; an aryl group which is substituted with at least one substituent group selected from the group consisting of linear or branched alkyl and alkoxy groups having 1-20 carbons and at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups having 1-20 carbons; an aryl group having a heterocyclic moiety of 2-24 carbons which is substituted with at least one substituent group selected from the group consisting of linear or branched alkyl and alkoxy groups having 1-20 carbons and at least one hetero-atom selected from the group consisting of F, S, N, O, P and Si; a substituted or unsubstituted trialkylsilyl group having 3-40 carbons; a substituted or unsubstituted arylsilyl group having 3-40 carbons; a substituted or unsubstituted carbazole group having 12-60 carbons; a substituted or unsubstituted phenothiazine group having 6-60 carbons; or a substituted or unsubstituted arylamine group having 6-60 carbons;
a, b and c are independently an integer from 1 to 3;
A is an aryl group which is unsubstituted or substituted with at least one substituent group selected from the group consisting of linear or branched alkyl and alkoxy groups having 1-20 carbons; an aryl group which is substituted with at least one substituent group selected from the group consisting of linear or branched alkyl and alkoxy groups having 1-20 carbons and at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups having 1-20 carbons; or an aryl group having a heterocyclic moiety of 2-24 carbons which is substituted with at least one substituent group selected from the group consisting of linear or branched alkyl and alkoxy groups having 1-20 carbons and at least one hetero-atom selected from the group consisting of F, S, N, O, P and Si;
Ar is selected from the group consisting of a substituted or unsubstituted aromatic moiety having 6-60 carbons, a substituted or unsubstituted heteroaromatic moiety having 2-60 carbons, and combinations thereof; and
l is an integer from 1 to 100,000, m is an integer from 0 to 100,000, and n is an integer from 1 to 100,000.

2. The electroluminescent polymer as set forth in claim 1, wherein said R₁ and R₂ are each independently selected from the group consisting of:

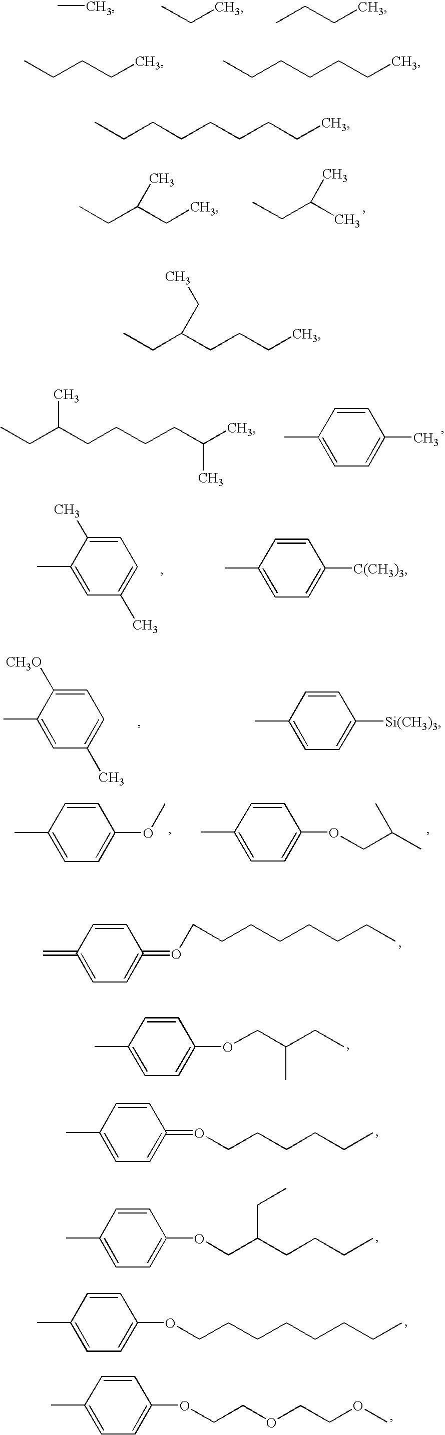

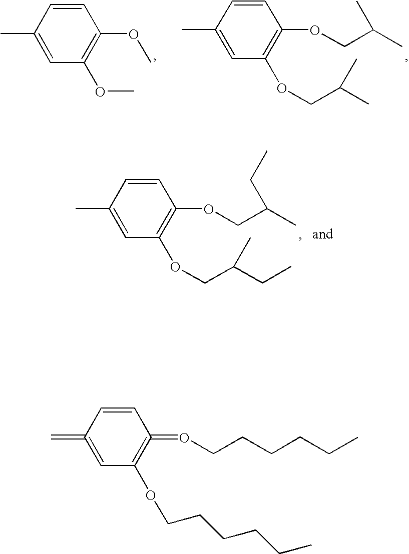

3. The electroluminescent polymer as set forth in claim 1, wherein said R₃ and R₄ are each independently selected from the group consisting of:
H,

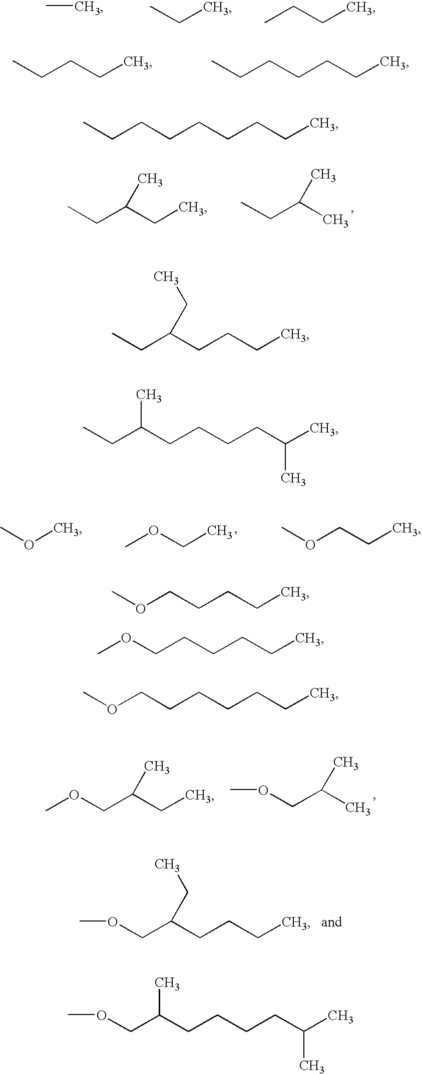

4. The electroluminescent polymer as set forth in claim 1, wherein said R₅ is selected from the group consisting of:
H, 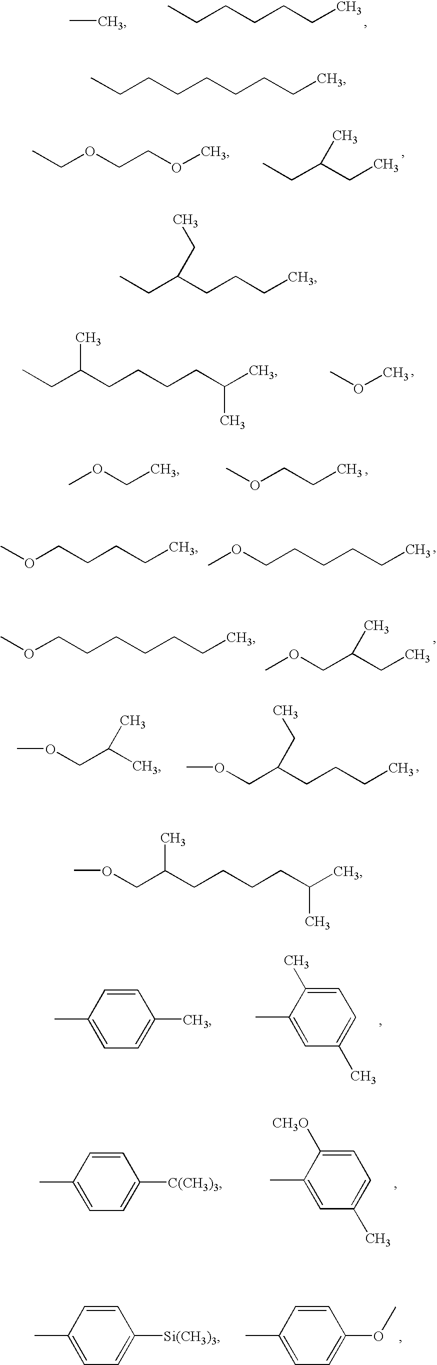 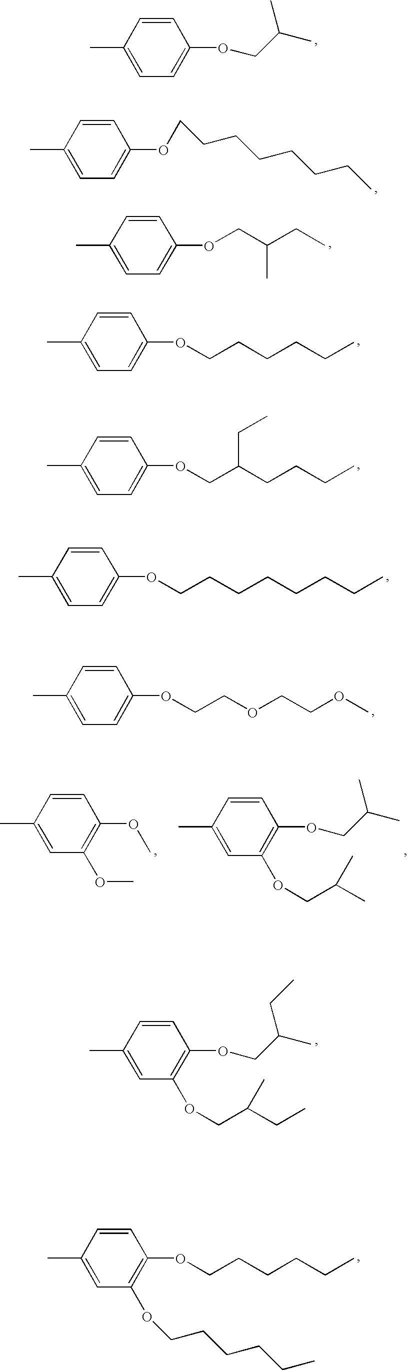 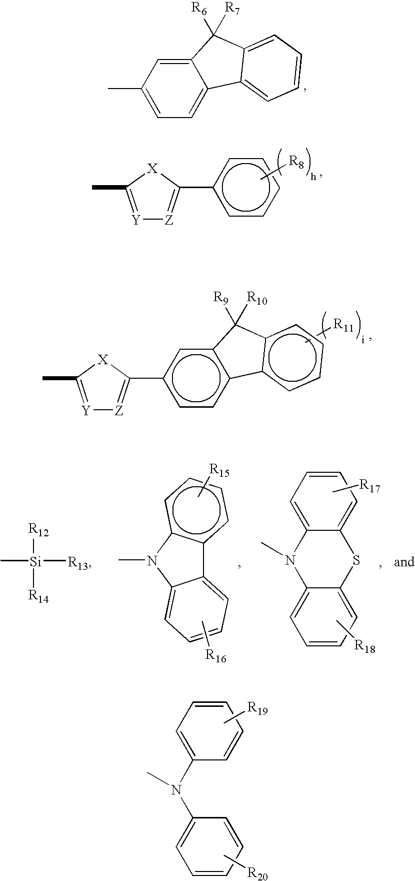
wherein R₆ and R₇ are independently a linear or branched alkyl group having 1-20 carbons;
R₈ is hydrogen or a linear or branched alkyl, alkoxy or trialkylsilyl group having 1-20 carbons;
R₉ and R₁₀ are independently a linear or branched alkyl group having 1-20 carbons, R₁₁ is hydrogen or a linear or branched alkyl, alkoxy or trialkylsilyl group having 1-20 carbons, X is O or S, Y and Z are each N, and h and i are the same or different, each being an integer from 1 to 3;
R₁₂, R₁₃ and R₁₄ are independently a linear or branched alkyl or alkoxy group having 1-20 carbons; or an aryl group which is unsubstituted or substituted with at least one substituent group selected from the group consisting of linear or branched alkyl and alkoxy groups having 1-20 carbons; and
R₁₅, R₁₆, R₁₇, R₁₈, R₁₉ and R₂₀ are independently hydrogen; a linear or branched alkyl or alkoxy group having 1-20 carbons; or an aryl group which is unsubstituted or substituted with at least one substituent group selected from the group consisting of linear or branched alkyl and alkoxy groups having 1-20 carbons;

5. The electroluminescent polymer as set forth in claim 1, wherein said R₃, R₄ and R₈ are each hydrogen.

6. The electroluminescent polymer as set forth in claim 1, wherein said A is: 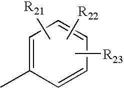
wherein R₂₁, R₂₂ and R₂₃ are independently hydrogen; a linear or branched alkyl or alkoxy group having 1-20 carbons; or a linear or branched alkyl or alkoxy group having 1-20 carbons and at least one hetero-atom selected from the group consisting of F, S, N, O, P and Si.

7. The electroluminescent polymer as set forth in claim 1, wherein said Ar is
(i) a substituted or unsubstituted arylene group having 6-60 carbons;
(ii) a substituted or unsubstituted heterocyclic arylene group having 2-60 carbons in which at least one hetero-atom selected from the group consisting of N, S, O, P and Si is incorporated in an aromatic ring;
(iii) a substituted or unsubstituted arylenevinylene group having 6-60 carbons;
(iv) a substituted or unsubstituted arylamine group having 6-60 carbons;
(v) a substituted or unsubstituted carbazole group having 12-60 carbons; or
(vi) combinations thereof,
in which Ar has a substituent selected from the group consisting of a linear or branched alkyl or alkoxy group having 1-20 carbons, an aryl group which is unsubstituted or substituted with at least one substituent group selected from the group consisting of linear or branched alkyl and alkoxy groups having 1-20 carbons, a cyano group (—CN), and a silyl group.

8. The electroluminescent polymer as set forth in claim 7, wherein said Ar is present in an amount of 5-15 mol % in the electroluminescent polymer, when said Ar is a substituted or unsubstituted arylamine group having 6-60 carbons.

9. The electroluminescent polymer as set forth in claim 1, wherein the electroluminescent polymer has a number average molecular weight from 700 to 10,000,000 and a molecular weight distribution from 1 to 100.

10. The electroluminescent polymer as set forth in claim 1, wherein the electroluminescent polymer is: 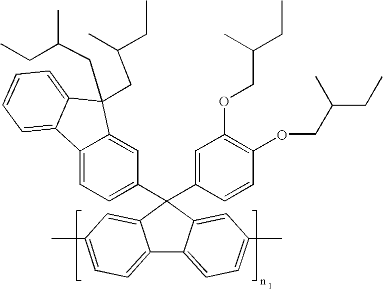
wherein n₁ is an integer from 1 to 100,000.

11. The electroluminescent polymer as set forth in claim 1, wherein the electroluminescent polymer is: 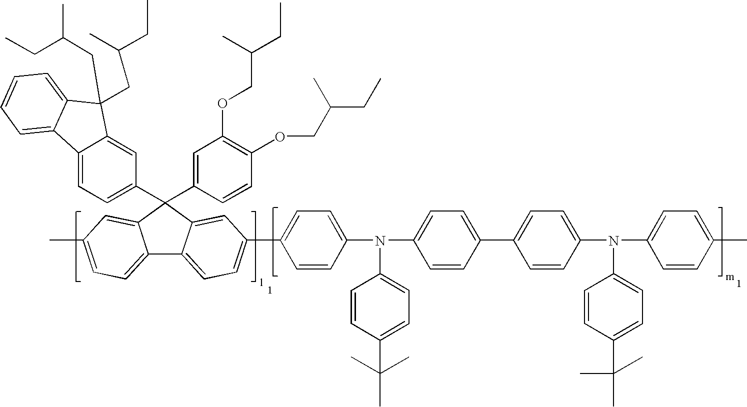
wherein l₁ is an integer from 1 to 100,000, and m₁ is an integer from 1 to 100,000.

12. The electroluminescent polymer as set forth in claim 1, wherein the electroluminescent polymer is: 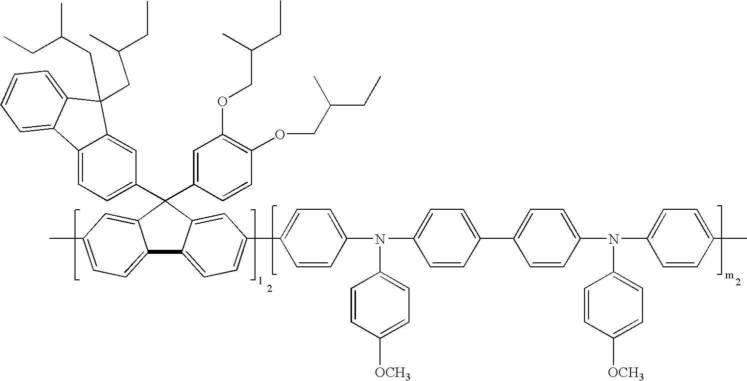
wherein l₂ is an integer from 1 to 100,000, and m₂ is an integer from 1 to 100,000.

13. An electroluminescent device having at least one layer comprising the electroluminescent polymer according to claim 1 between an anode and a cathode,
wherein the layer is an interlayer, a hole transport layer, a light emitting layer, an electron transport layer or a hole blocking layer.

14. The electroluminescent device as set forth in claim 13, wherein the electroluminescent device comprises at least one of the following layers between an anode and a cathode: a light emitting layer, an interlayer, a hole transport layer, or an electron transport layer.
